(19) United States
(12) Patent Application Publication
(10) Pub. No.: US 2012/0266954 A1
(43) Pub. Date: Oct. 25, 2012

(54) ORGANIC PHOTOVOLTAIC CELL

(76) Inventors: Takahiro Seike, Ibaraki (JP); Toshihiro Ohnishi, Ibaraki (JP)

(21) Appl. No.: 13/503,819

(22) PCT Filed: Oct. 26, 2010
(86) PCT No.: PCT/JP2010/068960

§ 371 Date: Apr. 24, 2012

(30) Foreign Application Priority Data
Oct. 29, 2009 (JP) 2009-249514

(51) Int. Cl. H01L 31/0224

(52) U.S. Cl. 136/256

(57) ABSTRACT

To suppress deterioration of electrical characteristics. An organic photovoltaic cell (10) comprises a pair of electrodes comprising a first electrode (32) and a second electrode (34); an active layer (50) placed between the pair of electrodes; and a metal layer (44) placed between either one of the pair of electrodes and the active layer, in which the metal layer is formed with a metal having an absolute value of a work function of 3.7 eV or more and 5.5 eV or less and having semiconductor properties when the metal is oxidized.

### TECHNICAL FIELD

The present invention relates to an organic photovoltaic cell.

### BACKGROUND ART

The organic photovoltaic cell comprises a pair of electrodes and an active layer that is placed between the pair of electrodes. Particularly, in many cases, an aluminum (Al) electrode made from Al, which has excellent electrical characteristics as a material, is used for the other electrode that faces a transparent substrate and a transparent electrode into which light goes.

However, it has been known that the Al electrode is easy to oxidize (deteriorate) by moisture and oxygen existing under external environment (the atmosphere). Such deterioration of the electrode material, or deterioration of organic compounds comprised in the active layer by moisture and oxygen passing through the electrode, may cause not only to worsen electrical characteristics of the cells but also to shorten the cell lifetime.

In order to solve problems of the deterioration of the electrode as described above and decrease in photovoltaic efficiency caused by the deterioration of the electrode, various solutions are investigated. For example, for stabilization of cell performance that is one of the purposes, an organic solar cell comprising a layered electrode in which a zinc oxide (ZnO) layer is formed on an indium-tin oxide (hereinafter, referred to as ITO) layer is used as a cathode, and an electrode that faces the layered electrode across the active layer and is made from gold (Au) have been known (refer to Patent Document 1).

### PATENT DOCUMENT

Patent Document 1: JP 2005-136315 A

### DISCLOSURE OF INVENTION

### Problem to be Solved by the Invention

However, constitution of conventional organic solar cells (organic photovoltaic cells) have been not sufficient for solving the problems such as the deterioration of the electrode, the deterioration of the active layer caused by the deterioration of the electrode, and the decrease in the photovoltaic efficiency due to those deteriorations.

Particularly, constitution that Patent Document 1 discloses is not sufficient for solving the problem of the deterioration of the electrode in an anode side. In addition, although silver (Ag) and gold used for the electrode material have resistance to oxidation, manufacturing cost of the electrode could increase because these metals are very expensive.

The inventors of the present invention have eagerly investigated an organic photovoltaic cell and a method for manufacturing thereof. As a result, the inventors have found that the problems can be solved by employing constitution in which a metal layer having certain characteristics is placed between an electrode and an active layer and have accomplished the present invention.

Namely, the present invention provides the following organic photovoltaic cell and the method for manufacturing thereof.

[1] An organic photovoltaic cell comprising:

a pair of electrodes comprising a first electrode and a second electrode;

an active layer placed between the pair of electrodes; and

a metal layer placed between either one of the pair of electrodes and the active layer, wherein

the metal layer is formed with a metal having an absolute value of a work function of 3.7 eV or more and 5.5 eV or less and having semiconductor properties when the metal is oxidized.

[2] The organic photovoltaic cell according to above [1], wherein the metal is a metal having n-type semiconductor properties when the metal is oxidized.
[3] The organic photovoltaic cell according to above [2], wherein the metal is any one of a metal selected from the group consisting of zinc, tin, titanium, and niobium.
[4] The organic photovoltaic cell according to above [1], wherein the metal is a metal having p-type semiconductor properties when the metal is oxidized.
[5] The organic photovoltaic cell according to above [4], wherein the metal is copper or nickel.
[6] The organic photovoltaic cell according to any one of above [1] to [5], further comprising a metal oxide film in contact with the metal layer.

### BRIEF DESCRIPTION OF DRAWINGS

FIG. 1 is a schematic cross-sectional view illustrating constitution of an organic photovoltaic cell.

### EXPLANATIONS OF LETTERS OR NUMERALS

10 organic photovoltaic cell
20 substrate
32 first electrode
34 second electrode
42 first metal layer
44 second metal layer
50 active layer

### DESCRIPTION OF EMBODIMENTS

Hereinafter, the present invention is described in detail with reference to the drawing. In the following description, the drawing only schematically illustrates shapes, sizes, and locations of constituent elements in such a degree that the present invention can be understood. Therefore, the present invention is not particularly limited by this description.

<Organic Photovoltaic Cell>

An organic photovoltaic cell according to the present invention comprises: an organic photovoltaic cell comprises a pair of electrodes of a first electrode and a second electrode; an active layer placed between the pair of electrodes; and a metal layer placed between either one of the pair of electrodes and the active layer, in which the metal layer is formed by a metal having an absolute value of a work function of 3.7 eV or more and 5.5 eV or less and having semiconductor properties when the metal is oxidized.

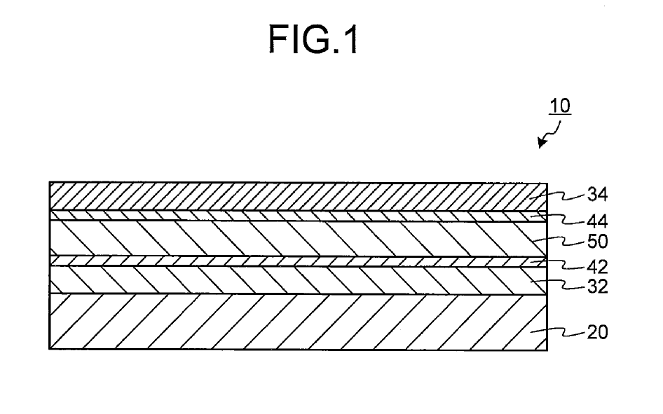

First, an example of structure of an organic photovoltaic cell is described with reference to FIG. 1. FIG. 1 is a schematic cross-sectional view illustrating structure of the organic photovoltaic cell.

As illustrated in FIG. 1, the organic photovoltaic cell 10 comprises a pair of electrodes of a first electrode 32 and a second electrode 34, and an active layer 50 that is placed between the pair of electrodes.

Among the pair of electrodes, at least one electrode into which light is incident, that is, at least one of the electrodes is a transparent or semitransparent electrode that can transmit incident light (sunlight) having a wavelength required for power generation.

The polarity of the first electrode 32 and the second electrode 34 may be any preferable polarity corresponding to a cell structure. It is also possible that the first electrode 32 is a cathode and the second electrode 34 is an anode.

The transparent or semitransparent electrodes may be a conductive metal oxide film or a semitransparent thin metal film. Specific examples of the transparent and semitransparent electrodes may include: films made of conductive materials such as indium oxide, zinc oxide, tin oxide, and mixtures thereof such as ITO and indium zinc oxide (IZO); NESA; and films made of gold, platinum, silver, copper, and the like. Films of ITO, IZO, and tin oxide are preferable for the transparent and semitransparent electrodes. Examples of methods for forming the electrode may include a vacuum evaporation method, a sputtering method, an ion plating method, and a plating method. As the electrode, organic transparent conductive films such as polyaniline and derivatives thereof and polythiophene and derivatives thereof may be used.

For an opaque electrode, electrode materials such as metals, conductive macromolecular compounds can be used.

Specific examples of the electrode material may include: metals such as lithium, sodium, potassium, rubidium, cesium, magnesium, calcium, strontium, barium, aluminum, scandium, vanadium, zinc, yttrium, indium, cerium, samarium, europium, terbium, and ytterbium; and alloys made of two or more of these metals; alloys made of one or more of the aforementioned metals and one or more metals selected from the group consisting of gold, silver, platinum, copper, manganese, titanium, cobalt, nickel, tungsten, and tin; graphite; intercalation graphite compound; polyaniline and derivatives thereof; and polythiophene and derivatives thereof. The alloys may be a magnesium-silver alloy, a magnesium-indium alloy, a magnesium-aluminum alloy, an indium-silver alloy, a lithium-aluminum alloy, a lithium-magnesium alloy, a lithium-indium ally, or a calcium-aluminum alloy.

The organic photovoltaic cell 10 comprises a first metal layer 42 and/or a second metal layer 44, which are sandwiched and joined between one of or both of the first electrode 32 and the second electrode 34, and the active layer 50. Here, a constitution example in which the organic photovoltaic cell 10 comprises both of the first metal layer 42 and the second metal layer 44 is described.

The first metal layer 42 and the second metal layer 44 are made of metals as the materials whose oxides have semiconductor properties, and the metals have an absolute value of their work functions of 3.7 eV or more and 5.5 eV or less.

The semiconductor properties of the metal oxides used for the first metal layer 42 and the second metal layer 44 are the n-type properties or the p-type properties.

Examples of the metals used for the first metal layer 42 and the second metal layer 44 having an absolute value of the work function of 3.7 eV or more and 5.5 eV or less and having the n-type semiconductor properties when the metals turn to oxides may include zinc (Zn) (4.33 eV-4.90 eV), tin (Sn) (4.42 eV-4.50 eV), titanium (Ti) (4.33 eV-4.58 eV), and niobium (Nb) (4.02 eV-4.87 eV). Values in parentheses are absolute values of the work functions. These absolute values of the work functions are values based on Kagaku Binran (Handbook of Chemistry), Kisohen (Basic Science Edition), 5th Edition, (written and edited by The Chemical Society of Japan, published by Maruzen, pp. II-608-II 610 (2004)).

The metal layer comprising any of zinc, tin, titanium, and niobium, which exhibits the n-type semiconductor properties when the metal turns to an oxide, as a material, can preferably be used as an electron transport layer.

Examples of the metals used for the first metal layer 42 and the second metal layer 44 having an absolute value of the work function of 3.7 eV or more and 5.5 eV or less, and having the p-type semiconductor properties when the metals turn to oxides may be copper (Cu) (4.48 eV-5.10 eV) or nickel (Ni) (3.70 eV-5.53 eV). Values in parentheses are absolute values of the work functions.

These absolute values of the work functions are values based on Kagaku Binran (Handbook of Chemistry), Kisohen (Basic Science Edition), 5th Edition, (written and edited by The Chemical Society of Japan, published by Maruzen, pp. II-608-II 610 (2004)).

The metal layer comprising material such as any of copper and nickel, which exhibit the p-type semiconductor properties when the metal turns to an oxide, can preferably be used as a hole transport layer.

The organic photovoltaic cell 10 is usually formed on the substrate. In other words, a layered structure comprising the first electrode 32, the first metal layer 42 which is provided on the first electrode 32, the active layer 50 which is provided on the first metal layer 42, the second metal layer 44 which is provided on the active layer 50, and the second electrode 34 which is provided on the second metal layer 44 is provided on the main surface of a substrate 20.

Here, when the first electrode 32 is an anode, the first metal layer 42 having semiconductor properties is the hole transport layer. In this case, the first metal layer 42 is preferably formed by copper or nickel, which has an absolute value of the work function of 3.7 eV or more and 5.5 eV or less, and has the p-type semiconductor properties when the metal turns to the oxide.

When the first electrode 32 is a cathode, the first metal layer 42 having semiconductor properties is the electron transport layer. In this case, the first metal layer 42 may be formed with zinc, tin, titanium, or niobium, which has an absolute value of the work function of 3.7 eV or more and 5.5 eV or less, and has the n-type semiconductor properties when the metal turns to the oxide.

Similarly, when the second electrode 34 is an anode, the second metal layer 44 having semiconductor properties is the hole transport layer. In this case, the second metal layer 44 may be formed with copper or nickel, which has an absolute value of the work function of 3.7 eV or more and 5.5 eV or less, and has the p-type semiconductor properties when the metal turns to an oxide.

When the second electrode 34 is a cathode, the second metal layer 44 having semiconductor properties is the electron transport layer. In this case, the second metal layer 44 may be formed with zinc, tin, titanium, or niobium, which has an absolute value of the work function of 3.7 eV or more and 5.5 eV or less, and has the n-type semiconductor properties when the metal turns to the oxide.

The first metal layer 42 and the second metal layer 44 may be preferably layers having an oxide film of their surfaces. In other words, the first metal layer 42 and the second metal layer 44 have metal oxide films in contact with each of the metal layers.

A material for the substrate 20 may be any material that is not chemically changed when the electrode is formed and a layer comprising an organic compound is formed. Examples of the material for the substrate 20 may include glasses, plastics, polymer films, and silicon.

When the substrate 20 is opaque, that is, the substrate does not transmit incident light, the second electrode 34 that faces the first electrode 32 and is provided on the opposite side of the substrate side (in other words, the electrode that is further from the substrate 20) is preferably a transparent electrode or a semitransparent electrode that can transmit necessary incident light.

The active layer 50 is placed between the first electrode 32 and the second electrode 34. The active layer 50 is a bulk hetero type organic layer comprising an electron acceptor compound (an n-type semiconductor) and an electron donor compound (a p-type semiconductor) in a mixed manner in this embodiment. The active layer 40 has an essential function for photovoltaic function that can generate charges (holes and electrons) using incident light energy.

As described above, the active layer 50 comprised in the photovoltaic cell 10 comprises the electron donor compound and the electron acceptor compound.

The electron donor compound and the electron acceptor compound are relatively determined by energy level of these compounds. Therefore, one compound can become either the electron donor compound or the electron acceptor compound.

Examples of the electron donor compounds may include pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amines in the main chain or side chains thereof, polyaniline and derivatives thereof, polythiophene and derivatives thereof, polypyrrole and derivatives thereof, polyphenylene vinylene and derivatives thereof, and polythienylene vinylene and derivatives thereof.

Examples of the electron acceptor compounds may include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ fullerene and derivatives thereof, phenanthrene derivatives such as bathocuproine, metal oxides such as titanium oxide, and carbon nanotubes. As the electron acceptor compounds, titanium oxide, carbon nanotubes, fullerenes, and fullerenes derivatives are preferable, and fullerenes and fullerene derivatives are particularly preferable.

Examples of the fullerenes may include C₆₀ fullerene, C₇₀ fullerene, C₇₆ fullerene, C₇₈ fullerene, and C₈₄ fullerene.

Examples of the fullerene derivatives may include derivatives of each of C₆₀ fullerene, C₇₀ fullerene, C₇₆ fullerene, C₇₈ fullerene, and C₈₄ fullerene. Specific structures of the fullerene derivatives may be the following structures.

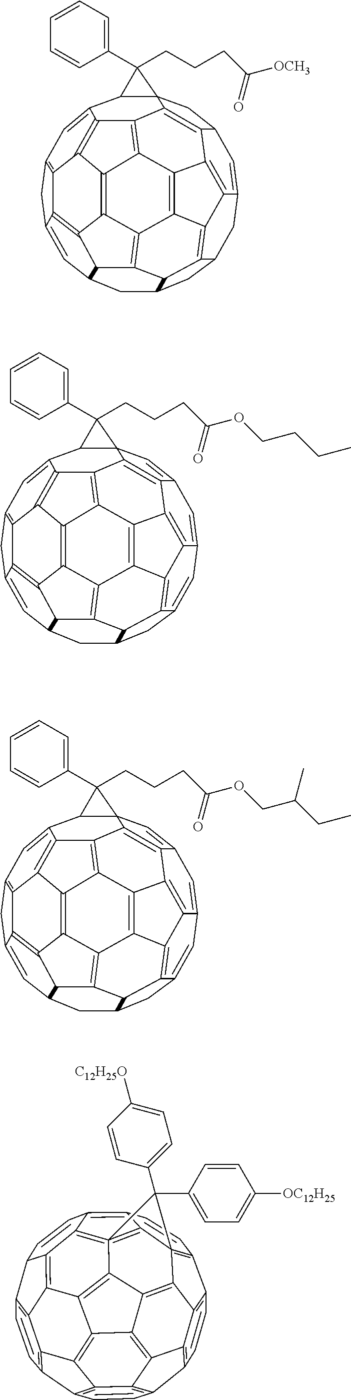

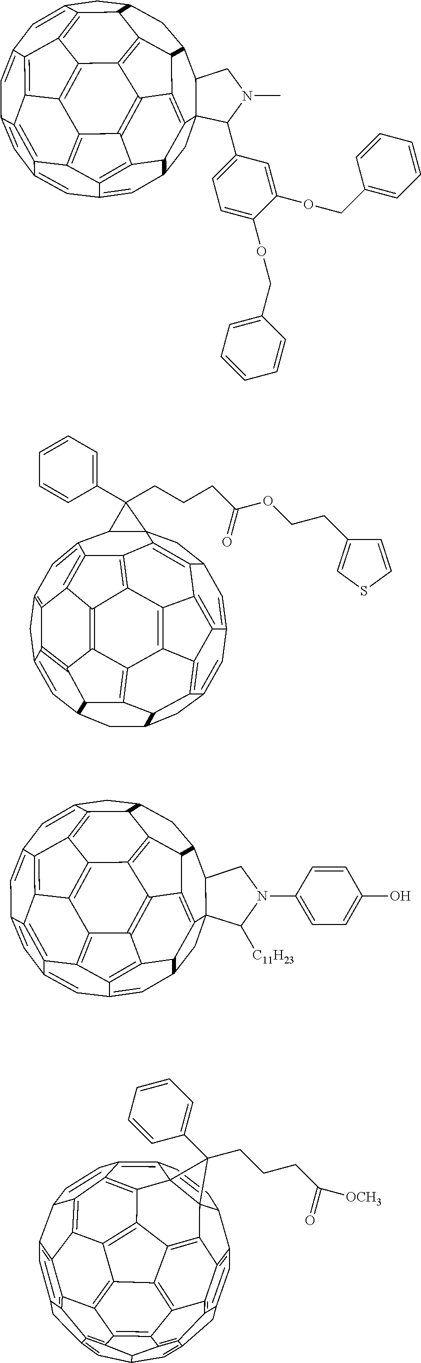

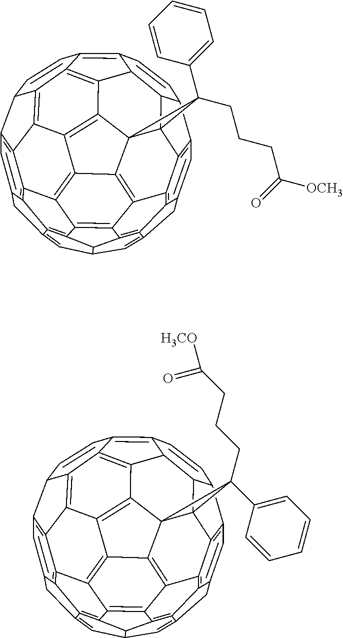

In addition, examples of the fullerene derivatives may include [6,6]-Phenyl C₆₁ butyric acid methyl ester (C₆₀PCBM), [6,6]-Phenyl C₇₁ butyric acid methyl ester (C₇₀PCMB), [6,6]-Phenyl C₈₅ butyric acid methyl ester (C₈₄PCBM), and [6,6]-Thienyl C61 butyric acid methyl ester.

When the fullerene derivatives are used as the electron acceptor compounds, a ratio of the fullerene derivative is preferably 10 parts by weight to 1000 parts by weight, and more preferably 20 parts by weight to 500 parts by weight, per 100 parts by weight of the electron donor compound.

A thickness of the active layer is preferably 1 nm to 100 μm, more preferably 2 nm to 1000 nm, further preferably 5 nm to 500 nm and particularly preferably 20 nm to 200 nm.

In this embodiment, the single layered active layer in which the active layer 50 is the bulk hetero type that is made by mixing the electron acceptor compound and the electron donor compound is described. However, the active layer 50 may be constituted by a plurality of layers.

For example, the active layer may be a hetero-junction type in which an electron acceptor layer comprising the electron acceptor compound such as the fullerene derivative and an electron donor layer comprising the electron donor compound such as P3HT are joined.

A ratio of the electron acceptor compound in the bulk hetero type active layer comprising the electron acceptor compound and the electron donor compound is preferably 10 parts by weight to 1000 parts by weight, and more preferably 50 parts by weight to 500 parts be weight, per 100 parts by weight of the electron donor compound.

Examples of layer constitution in which the organic photovoltaic cell can be formed are as follows.

a) Anode/Active layer/Cathode
b) Anode/Hole transport layer/Active layer/Cathode
c) Anode/Active layer/Electron transport layer/Cathode
d) Anode/Hole transport layer/Active layer/Electron transport layer/Cathode
e) Anode/Electron supply layer/Electron acceptor layer/Cathode
f) Anode/Hole transport layer/Electron donor layer/Electron acceptor layer/Cathode
g) Anode/Electron donor layer/Electron acceptor layer/Electron transport layer/Cathode
h) Anode/Hole transport layer/Electron donor layer/Electron acceptor layer/Electron transport layer/Cathode
(Here, the symbol “/” represents that layers sandwiching the symbol “/” are adjacently stacked each other).

The layer structure may be either a form in which the anode is placed at the closer side to the substrate or a form in which the cathode is placed at the closer side to the substrate.

Each of the layers may be constituted by not only a single layer but also a layered body made of two or more layers.

In the layer structure example, the electron transport layer corresponds to the metal layer comprising any of zinc, tin, titanium, and niobium, which exhibits the n-type semiconductor properties when the metal turns to the oxide, as a material, and the hole transport layer corresponds to the metal layer comprising material such as any of copper and nickel, which exhibits the p-type semiconductor properties when the metal turns to the oxide.

The organic photovoltaic cell according to the present invention comprises the metal layer made of the metal that has an absolute value of the work function of 3.7 eV or more and 5.5 eV or less, and in which an oxide has semiconductor properties when the metal is oxidized. Therefore, the organic photovoltaic cell has high durability to deterioration factors such as moisture and oxygen in external environment. Consequently, penetration of moisture and oxygen into the active layer caused by the deterioration can be prevented. The active layer is effectively protected from moisture and oxygen existing in the external environment by the metal layer. As a result, decrease in photovoltaic efficiency caused by deterioration of the organic compound comprised in the active layer can be suppressed. When an oxide layer is formed by oxidizing the surface of the metal layer, the metal oxide of the metal being a material for the metal layer can also be a compound having semiconductor properties. Therefore, decrease in photovoltaic efficiency can be suppressed without largely impairing a charge transport property.

<Method for Manufacturing>

Subsequently, a method for manufacturing the organic photovoltaic cell is described with reference to FIG. 1. Here, it is described with respect to a constitution example comprising both of the first metal layer 42 and the second metal layer 44.

First, the substrate 20 is prepared for manufacturing the organic photovoltaic cell 10. The substrate 20 is a planar substrate having two facing main surfaces. For preparing the substrate 20, a substrate in which a conductive material thin film being possible to be a material for an electrode such as indium tin oxide is previously provided on the one main surface of the substrate 20 may be prepared.

When the conductive material thin film is not provided on the substrate 20, the conductive material thin film is formed on one main surface of the substrate 20 by any preferable method. Subsequently, the conductive material thin film is patterned. The conductive material thin film is patterned by any preferable method such as a photolithography step and an etching step to form the first electrode 32.

Subsequently, the first metal layer 42 is formed on the substrate 20 on which the first electrode 32 is formed. When the first electrode 32 is an anode, the first metal layer 42 is formed by copper or nickel, which has an absolute value of the work function of 3.7 eV or more and 5.5 eV or less, and has the p-type semiconductor properties when the metal turns to an oxide. On the other hand, when the first electrode 32 is a cathode, the first metal layer 42 is preferably formed by zinc, tin, titanium, or niobium, which has an absolute value of the work function of 3.7 eV or more and 5.5 eV or less, and has the n-type semiconductor properties when the metal turns to the oxide.

The first metal layer 42 may be formed so that a film thickness thereof is preferably in a range from 2 nm to 50 nm.

Subsequently, the active layer 50 is formed on the first metal layer 42 in accordance with a ordinary procedure. The active layer 50 is formed by a coating method such as a spin coating method in which a coating liquid made by mixing a solvent and any preferable material for the active layer is applied.

Subsequently, the second metal layer 44 is formed on the active layer 50. When the first electrode 32 is an anode (when the second electrode is a cathode), the second metal layer 44 is formed by zinc, tin, titanium, or niobium, which has an absolute value of the work function of 3.7 eV or more and 5.5 eV or less, and has the n-type semiconductor properties when the metal turns to the oxide. On the other hand, when the first electrode 32 is a cathode (when the second electrode is an anode), the second metal layer 44 is preferably formed by copper or nickel, which has an absolute value of the work function of 3.7 eV or more and 5.5 eV or less, and has the p-type semiconductor properties when the metal turns to the oxide.

The second metal layer 44 may be formed so that a film thickness thereof is preferably in a range from 2 nm to 50 nm.

The first metal layer 42 and the second metal layer 44 are manufactured by any conventionally known method preferable for manufacturing a thin metal film such as vacuum evaporation and plating.

The first metal layer 42 and the second metal layer 44 are preferably formed as layers comprising an oxide layer of their surfaces. In other words, each of the first metal layer 42 and the second metal layer 44 is formed so as to have a metal oxide film in contact with each of the metal layers.

The layer made of zinc, tin, titanium, niobium, copper, or nickel as described above provides semiconductor properties by forming the oxide layer of the surface thereof, when the layer is oxidized by oxygen and the like in external environment (air). Consequently, the semiconductor properties are obtained by oxidation without performing any particular treatment.

For the first metal layer 42 and the second metal layer 44, the oxide layers are preferably formed on the surfaces thereof by preferably and positively exposing the layers to the external environment after film formation. This exposing step may be performed after patterning step when patterning is required for the first metal layer 42 and the second metal layer 44.

The first metal layer 42 and the second metal layer 44 may more preferably be oxidized after film forming by any preferable known oxidation step such as ozone plasma treatment or thermal oxidation treatment. When these steps are performed, electrical characteristics can be more stabilized because a degree of oxidation can be uniformed.

Subsequently, the second electrode 34 is formed on the second metal layer 44. The second electrode 34 can be formed by a film forming method using, for example, a coating liquid, that is, a solution.

Usable methods for forming the film may includes coating methods such as a spin coating method, a casting method, a microgravure coating method, a gravure coating method, a bar coating method, a roll coating method, a wire bar coating method, a dip coating method, a spray coating method, a screen printing method, a gravure printing method, a flexographic printing method, an offset printing method, an ink-jet printing method, a dispenser printing method, a nozzle coating method, and a capillary coating method. Preferable are the spin coating method, the flexographic printing method, the gravure printing method, the ink-jet printing method, and the dispenser printing method.

A solvent used for these methods for forming the film that use the solution is not particularly limited as long as the solvent dissolves the above-described material for the second electrode 34, that is, an alkali metal salt or an alkaline earth metal salt, and a conductive material.

Examples of such solvents may include unsaturated hydrocarbon solvents such as toluene, xylene, mesitylene, tetralin, decalin, bicyclohexyl, butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether solvents such as tetrahydrofuran, and tetrahydropyran.

Forming the second electrode 34 is completed by drying the applied and formed layers in preferable conditions for the material and the solvent under any preferable atmosphere such as a nitrogen gas atmosphere.

The organic photovoltaic cell can be manufactured by performing the above-described steps.

<Operation>

Here, an operation mechanism of the organic photovoltaic cell is simply described. Energy of incident light that transmits though the transparent or semitransparent electrode and is incident into the active layer is absorbed by the electron acceptor compound and/or the electron donor compound, and thereby exciters in which electrons and holes are combined are generated. When the generated exciters move and reach to a hetero-junction interface where the electron acceptor compound and the electron donor compound are joined, difference of each of HOMO energy and LUMO energy at the interface causes separation of electrons and holes and generates charges (electrons and holes) that can move independently. The organic photovoltaic cell can take out electric energy (electric current) to outside of the cell by moving the generated charges to the electrodes (the cathode and the anode).

<Application>

The organic photovoltaic cell manufactured by the method for manufacturing according to the present invention generates photovoltaic power between the electrodes by irradiating the first electrode and/or the second electrode that are (is) transparent or semitransparent electrode(s) with light such as sunlight, and thereby can operate as an organic thin film solar cell. The organic thin film solar cell also can be used as an organic thin film solar cell module by stacking a plurality organic thin film solar cells.

In addition, the organic photovoltaic cell manufactured by the method for manufacturing according to the present invention generates photocurrent by making light incident into cells through the electrodes that are transparent or semitransparent in a state in which voltage is applied to the first electrode and the second electrode or in a state in which voltage is not applied. Therefore, the organic photovoltaic cell manufactured by the method for manufacturing according to the present invention can be operated as an organic light sensor. The organic light sensor also can be used as an organic image sensor by stacking a plurality of organic light sensors.

### EXAMPLES

### Example 1

After washing a glass substrate on which an ITO film was formed in a thickness of 150 nm by a spattering method with acetone, ultraviolet ozone cleaning treatment was performed for 15 minutes by an ultraviolet ozone irradiation device equipped with a low-pressure mercury vapor lamp (Type: UV-312, manufactured by Technovision, Inc.) to form an ITO electrode being the first electrode having a clear surface.

Subsequently, PEDOT (Trade name Baytron P AI4083, Lot. HCD070109, manufactured by Starck) layer was formed by applying PEDOT on the surface of the ITO electrode by the spin coating method, and drying the applied layer at 150° C. for 30 minutes in the atmosphere.

Subsequently, after adding poly (3-hexyl thiophene) (P3HT) (Trade name: lisicon SP001, Lot. EF431002, manufactured by Merck) as an electron donor compound and PCBM (Trade Name: E100, Lot. 7B0168-A, manufactured by Frontier Carbon Corporation) as a fullerene derivative being an electron acceptor compound to an ortho-dichlorobenzene solvent so that P3HT was 1.5% by weight and PCBM was 1.2% by weight and stirring at 70° C. for 2 hours, the mixture was filtered with a filter having a pore diameter of 0.2 μm to prepare a coating liquid 1. The coating liquid 1 was applied on the ITO electrode by the spin coating method, and thereafter, the applied layer was heat treated at 150° C. for 3 minutes in nitrogen gas atmosphere to form the active layer. A film thickness of the active layer after heat treatment was about 100 nm.

Thereafter, zinc (Zn) having a thickness of 4 nm and aluminum (Al) having a thickness of 70 nm as the second electrode was deposited in this order by a vacuum deposition device. All degree of vacuum during the deposition was 1-9×10⁻⁴ Pa. A shape of the obtained organic thin film solar cell being the organic photovoltaic cell was a square of 2 mm×2 mm.

### Example 2

An organic thin film solar cell was prepared by the same method in Example 1 except that tin (Sn) was deposited instead of Zn by the vacuum deposition device.

### Example 3

After washing a glass substrate on which an ITO film was formed in a thickness of 150 nm by a spattering method with acetone, ultraviolet ozone cleaning treatment was performed for 15 minutes by the ultraviolet ozone irradiation device equipped with the low-pressure mercury vapor lamp (Type: UV-312, manufactured by Technovision, Inc.) to form an ITO electrode having a clear surface.

Subsequently, a TiO₂ dispersion (trade name PASPL HPW-10R, lot. BT-18, manufactured by JGC Catalysts and Chemicals Ltd.) was applied on the surface of the ITO electrode by the spin coating method. Subsequently, the TiO₂ film was formed by drying at 150° C. for 30 minutes in the atmosphere.

Subsequently, after adding poly (3-hexyl thiophene) (P3HT) as an electron donor compound and PCBM as a fullerene derivative being an electron acceptor compound to an ortho-dichlorobenzene solvent so that P3HT was 1.5% by weight and PCBM was 1.2% by weight and stirring at 70° C. for 2 hours, the mixture was filtered with a filter having a pore diameter of 0.2 μm to prepare a coating liquid. Subsequently, the coating liquid was applied on the TiO₂ film by the spin coating method, and the applied film was heat treated at 150° C. for 3 minutes in nitrogen gas atmosphere to form the active layer. A film thickness of the active layer after heat treatment was about 100 nm.

Thereafter, copper (Cu) having a thickness of 4 nm and aluminum (Al) having a thickness of 70 nm as the second electrode was deposited in this order by the vacuum deposition device. All degree of vacuum during the deposition was 1×10⁻⁴ Pa to 9×10⁻⁴ Pa.

### Comparative Example 1

An organic thin film solar cell was prepared by the same method in Example 1 except that deposition step of Zn by the vacuum deposition device was not performed.

### Comparative Example 2

An organic thin film solar cell was prepared by the same method in Example 3 except that deposition step of Cu by the vacuum deposition device was not performed.

<Evaluation>

For photovoltaic efficiency of the obtained organic thin film solar cell, current and voltage were measured using a solar simulator (trade name YSS-80, manufactured by Yamashita Denso Corporation) by irradiating with light having irradiated illumination intensity of 100 mW/cm² through an AM1.5G filter, and open-circuit voltage (an initial value), which is one factor for calculating the photovoltaic efficiency, was measured. Moreover, an open-circuit voltage of the organic thin film solar cell after leaving to stand for 10000 hours at dark place in a room in the atmosphere was measured. Ratios of the open-circuit voltage after 10000 hours to the initial value are listed in Table 1.

TABLE 1
Ratios of the open-circuit voltage (after 10000 hours)
to the open-circuit voltage (initial value)

| | ratios |
|---|---|
| Example 1 | 0.87 |
| Example 2 | 0.75 |
| Example 3 | 0.87 |
| Comparative | 0.28 |
| example 1 | |
| Comparative | 0.31 |
| example 2 | |

<Results>

As clear from Table 1, any of the organic thin film solar cells of Example 1, Example 2, and Example 3 had smaller decrease in the open-circuit voltage over time than the organic thin film solar cells of Comparative example 1 and Comparative example 2.

When the organic thin film solar cell having any of the Zn layer (Example 1), the Sn layer (Example 2), and the Cu layer (Example 3) is compared with the organic thin film solar cell not having any of them, it was demonstrated that the photovoltaic efficiency after leaving to stand, in other words, degree in decrease in electrical characteristics over time is small.

### INDUSTRIAL APPLICABILITY

The present invention is useful because the present invention provides the organic photovoltaic cell.

1. An organic photovoltaic cell comprising:
a pair of electrodes comprising a first electrode and a second electrode;
an active layer placed between the pair of electrodes; and
a metal layer placed between either one of the pair of electrodes and the active layer, wherein
the metal layer is formed with a metal having an absolute value of a work function of 3.7 eV or more and 5.5 eV or less, and having semiconductor properties when the metal is oxidized.

2. The organic photovoltaic cell according to claim 1, wherein the metal is a metal having n-type semiconductor properties when the metal is oxidized.

3. The organic photovoltaic cell according to claim 2, wherein the metal is any one of a metal selected from the group consisting of zinc, tin, titanium, and niobium.

4. The organic photovoltaic cell according to claim 1, wherein the metal is a metal having p-type semiconductor properties when the metal is oxidized.

5. The organic photovoltaic cell according to claim 4, wherein the metal is copper or nickel.

6. The organic photovoltaic cell according to claim 1, further comprising a metal oxide film in contact with the metal layer.
